(19) United States
(12) Patent Application Publication
(10) Pub. No.: US 2014/0247400 A1
(43) Pub. Date: Sep. 4, 2014

(54) TOUCH SCREEN PANEL

(71) Applicant: DONGBU HITEK CO., LTD., Seoul (KR)

(72) Inventors: Jin Ah LEE, Incheon (KR); Hyun SONG, Suwon-si (KR); Young Wook KIM, Seoul (KR); Won Cheol HONG, Seoul (KR); Joon SONG, Seoul (KR); Ae Young MA, Gunsan-si (KR); Jon Ghwan KO, Gwangmyeong-si (KR); Han Kyung KIM, Bucheon-si (KR)

(73) Assignee: DONGBU HITEK CO., LTD., Seoul (KR)

(21) Appl. No.: 13/803,846

(22) Filed: Mar. 14, 2013

(30) Foreign Application Priority Data
Mar. 4, 2013 (KR) 10-2013-0023049

(51) Int. Cl. G06F 3/041; H05K 3/00; G06F 1/16

(52) U.S. Cl. CPC G06F 3/0416; G06F 1/169; H05K 3/00
USPC 349/12; 29/846

(57) ABSTRACT

Touch screen panels and methods of manufacturing the same are provided. A touch screen panel can include a plurality of driving lines arranged in a first direction and a plurality of sensing lines arranged in a direction intersecting the first direction. The driving lines can each include at least one hole and/or at least one groove in an area intersecting the sensing line.

### CROSS-REFERENCE TO RELATED APPLICATION

This application claims the benefit under 35 U.S.C. §119 of Korean Patent Application No. 10-2013-0023049, filed Mar. 4, 2013, which is hereby incorporated by reference in its entirety.

### BACKGROUND

In general, a touch screen panel is an input device inputting a user's command by selecting an instruction displayed on the screen of an image display device. The selection is made by touching the screen (e.g., with a finger or a stylus pen).

The touch screen panel is typically provided at the front face of an image display device and converts a contact position that directly contacts the hands of a user or an object into electrical signals. An instruction selected at the contact position is received as an input signal. Since such a touch screen panel may replace an additional input device such as a keyboard and a mouse that otherwise may be connected to an image display device, it has become more and more widely used.

FIGS. 1 and 2 are views illustrating a change in charge quantity when a user touches a touch screen panel.

The touch screen panel includes electrodes that vertically intersect in the X and Y directions to recognize a user's touch position. The electrodes in the X direction may be referred to as a driving line, and the electrodes in the Y direction may be referred to as a sensing line.

A user's touch position is detected by detecting a capacitance difference between the driving line and the sensing line.

Referring to FIG. 1, an electric field between a driving electrode and a sensing electrode is shown when there is no user's touch. Referring to FIG. 2, an electric field between the electrodes is shown when there is a user's touch.

Ca indicates a charge quantity parasitic on a point where a sensing line and a driving line meet in parallel, Cb indicates a charge quantity at a point where a sensing line and a driving line meet in non-parallel, and Cc indicates a charge quantity exiting through a ground if there is a user's touch.

In this case, a change of charge quantity between a state of no user's touch and a state of a user's touch is calculated using Equation 1.

$$Δ C = \frac{Ca + Cb}{Ca + Cb} - \frac{Ca + Cb - Cc}{Ca + Cb} = \frac{Cc}{Ca + Cb} \qquad Equation 1$$

In order to sensitively recognize a user's touch, a charge quantity difference AC between a state before a touch and a state after a touch needs to be large. As shown in Equation 1, if the value of Ca or Cb decreases, the charge quantity difference AC between the before-touch state and the after-touch state may be greatly altered.

### BRIEF SUMMARY

Embodiments of the subject invention provide electrode structures, and method of manufacturing and using the same, in which a user's touch may be more accurately sensed in a touch screen panel.

In an embodiment, a touch screen panel can include: a plurality of driving lines arranged in a first direction; and a plurality of sensing lines arranged in a direction perpendicular to and intersecting the first direction. Each driving line can include, in an area intersecting a sensing line: at least one hole, at least one groove, or both.

In another embodiment, a touch screen panel can include: a plurality of driving lines arranged in a first direction; a plurality of sensing lines arranged in a direction perpendicular to and intersecting the first direction; a plurality of trace lines electrically connected to the driving lines, respectively, such that each driving line is electrically connected to one trace line; and a plurality of contact units in direct physical contact with the driving lines, respectively, such that each driving line is in direct physical contact with one contact unit. Each of the driving lines can include a plurality of divided sub lines all connected to the same contact unit.

In another embodiment, a method of fabricating a touch screen panel can include: forming a plurality of driving lines arranged in a first direction; forming a plurality of sensing lines arranged in a direction perpendicular to and intersecting the first direction; and forming on each driving line, in an area intersecting a sensing line: at least one hole, at least one groove, or both.

### BRIEF DESCRIPTION OF THE DRAWINGS

FIGS. 1 and 2 are views illustrating a change in charge quantity when a user touches a touch screen panel.

FIG. 3 is a cross-sectional view of a configuration of a display device including a touch screen panel according to an embodiment of the subject invention.

FIGS. 4 and 5 are views of a form of a driving line according to an embodiment of the subject invention.

FIG. 6 is a view of a form of a driving line according to an embodiment of the subject invention.

FIGS. 7 and 8 are views of a form of a driving line according to an embodiment of the subject invention.

FIG. 9 is a view of a form of a driving line according to an embodiment of the subject invention.

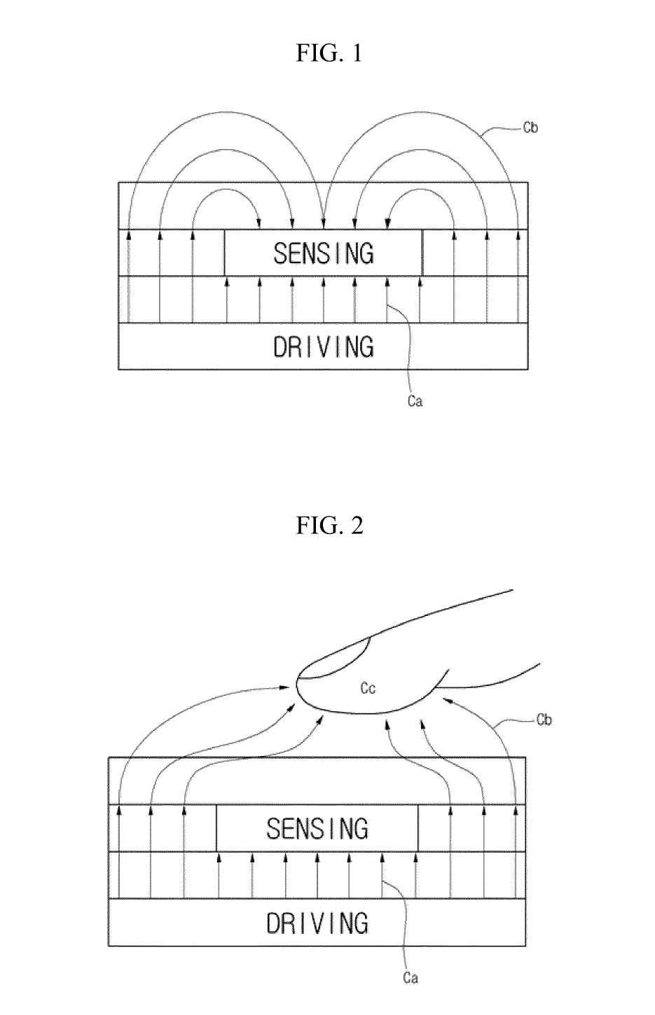

### DETAILED DESCRIPTION

Reference will now be made in detail to the embodiments of the present disclosure, examples of which are illustrated in the accompanying drawings.

When the terms “on” or “over” are used herein, when referring to layers, regions, patterns, or structures, it is understood that the layer, region, pattern, or structure can be directly on another layer or structure, or intervening layers, regions, patterns, or structures may also be present. When the terms “under” or “below” are used herein, when referring to layers, regions, patterns, or structures, it is understood that the layer, region, pattern, or structure can be directly under the other layer or structure, or intervening layers, regions, patterns, or structures may also be present.

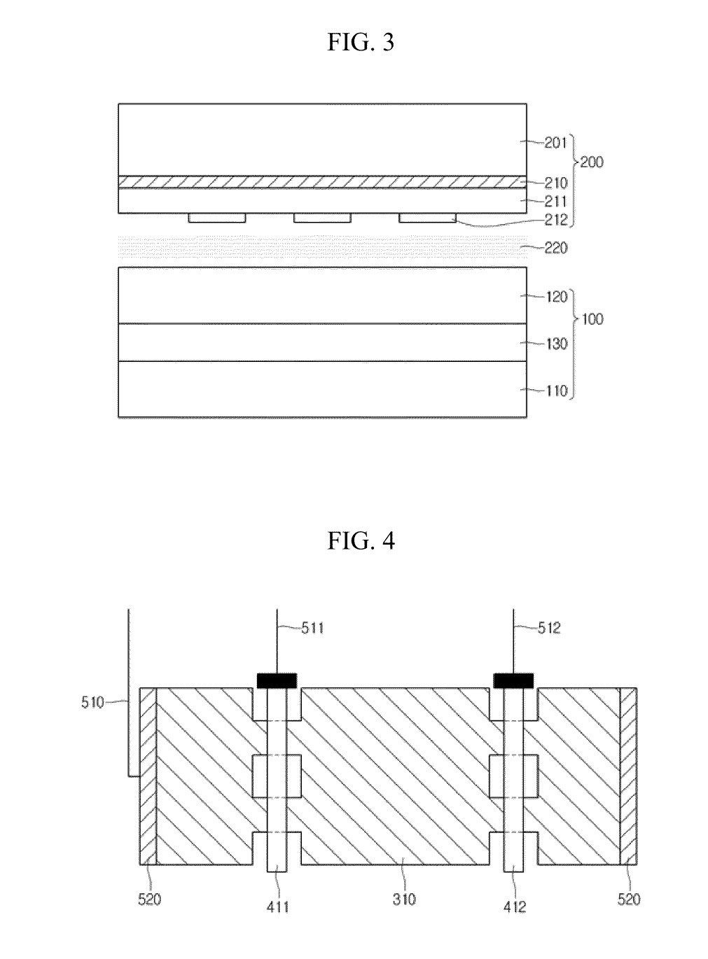

FIG. 3 is a cross-sectional view of a configuration of a display device including a touch screen panel according to an embodiment of the present invention.

For example, a touch screen panel can be configured in a display device such as a liquid crystal display (LCD), though embodiments are not limited thereto.

In an embodiment, a touch screen panel can include an X electrode 210 for detecting touch, a Y electrode 212, and an insulating layer 211 between the X electrode 210 and the Y electrode 212. These elements can all be provided on the inner side of a substrate 201. The substrate can be, for example, glass (e.g., cover glass), though embodiments are not limited thereto. The X electrode 210 and the Y electrode 212 can be arranged perpendicular to each other. In certain embodiments, the X electrode 210 can be a driving line, and the Y electrode 212 can be a sensing line. Also, a touch detecting unit in an array can be configured at the inner side of the substrate 201, and such a substrate-integrated touch panel 200 and a liquid crystal panel 100 can be bonded by an adhesive layer 220.

For example, a liquid crystal panel 100 can include a first substrate 110 and a second substrate 120 facing the first substrate 110. The liquid crystal panel 100 can further include a liquid crystal layer 130 filling in between the first 110 and second 120 substrates. In an embodiment, a thin film transistor array including a gate line and a data line intersecting to define a pixel region and a pixel electrode formed on the pixel region can be formed on the first substrate 110.

Also, in an embodiment, a color filter array including a black matrix layer, a color filter layer, and a common electrode can be formed on the second substrate 120. The common electrode can be formed on the front face of the second substrate 120. In some cases, the common electrode and the pixel electrode can be alternately formed in the pixel region on the first substrate 110.

In an embodiment, a pad unit can be formed at one side of the substrate 201. The pad unit can include a plurality of pads to apply a signal to each of the X electrode 210 and the Y electrode 212. Each of the plurality of pads can be connected to the X electrode 210 and the Y electrode 212.

Capacitance can be formed between the X electrode and the Y electrode arranged in a matrix. By scanning a capacitance map including rows and columns, a capacitance value for each node (for example, a lattice point or a pixel) of a grid can be read. If there is no user's touch, an electric field line occurring at a lattice point can be changed and a capacitance between two electrodes can be reduced at a corresponding lattice point.

In order to more sensitively detect a change in capacitance, as mentioned above, a value of a parasitic capacitance between the X electrode 210 and the Y electrode 212 must be small. In order to lower such a parasitic capacitance value, an area where the X electrode 210 and the Y electrode 212 intersect should be small.

Hereinafter, the X electrode 210 is referred to as a driving line or a driving electrode, and the Y electrode 212 is referred to as a sensing line or a sensing electrode. Also, examples of the form of an electrode according to embodiments of the present invention will be described.

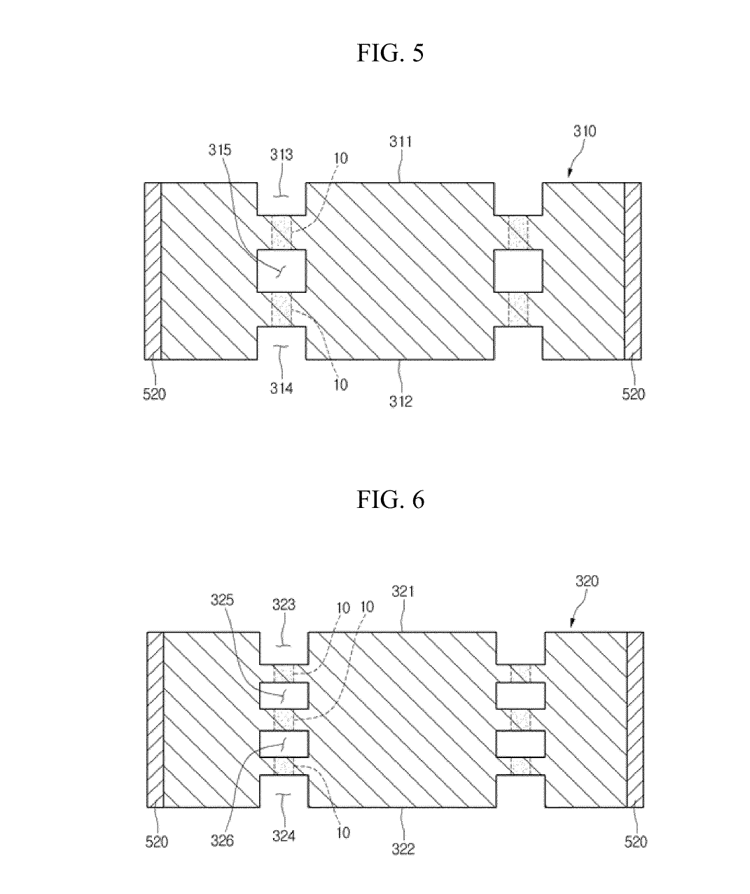

FIGS. 4 and 5 are views of a form of a driving line according to an embodiment of the subject invention. FIG. 6 is a view of a form of a driving line according to another embodiment of the subject invention.

When the form of an electrode/line is described, one line will be mainly described for exemplary purposes. However, it should be understood that a plurality of such lines may be present in a touch screen device according to embodiments of the subject invention. Driving lines shown in FIGS. 4 to 9 are just one of the electrodes arranged in the X-axis in a touch screen panel, and a plurality of such driving lines can be gathered to form one or more X electrodes for touch recognition of a touch screen panel. Also, though a small number of sensing lines may be shown in the figures for exemplary purposes, it should be understood that a plurality of such lines may be present in a touch screen device according to embodiments of the subject invention.

Referring to FIGS. 4 and 5, one driving line 310 in the X-axis is shown for exemplary purposes, and two sensing lines 411 and 412 vertically intersecting the driving line 310 are shown for exemplary purposes.

A mutual capacitance between a driving line and a sensing line can be transmitted to a controller (not shown) through trace lines 510, 511, and 512, and then, a touch position can be recognized by the controller. That is, a trace line 510 can be electrically connected to the driving line 310, and trace lines 511, 512 can be electrically connected to the sensing lines 411, 412.

A contact unit 520 for electrical connection with the trace line 510 can be formed on each end part of the driving line 310. Likewise, contact units (not labeled) for contacting the trace lines 511 and 512 can be formed on each end part of the sensing lines 411 and 412.

In an embodiment, the form of the driving line 310 can include at least one groove and at least one hole in order to reduce an area intersecting (e.g., provided directly over or directly under) a sensing line.

FIG. 5 is an enlarged view illustrating a portion of a driving line 310. Contact units 520 connected to a trace line can be formed at both ends of the driving line 310, and a first groove 313, a second groove 314, and a hole 315 can be formed in an area intersecting a sensing line.

In more detail, the first groove 313 and the second groove 314 can have a form bent from one side 311 and the other side 312, respectively, of the driving line 310 toward the line inside. That is, the first groove 313 can have a groove shape in the first side 311 of the driving line 310, and the second groove 314 can have a groove shape in the second side 312, opposite to the first side 311, of the driving line 310.

Also, the hole 315 can be formed in an area between the first groove 313 and the second groove 314 in order to further reduce an area intersecting a sensing line. For example, the hole 315 can be formed in an area between the first groove 313 and the second groove 314 along an area 10 where a sensing line intersects. Due to the shape of the driving electrode 310, an intersection area 10 (i.e., an area intersecting the sensing line 411) can be further reduced.

As mentioned above, a capacitance value parasitic on the driving line and the sensing line can be reduced by reducing the intersection area between the driving line and the sensing line. This further increases a change in capacitance quantity during a user's touch and thus, through this, the user's touch sensitivity can be improved.

Referring to FIG. 6, in another embodiment, a driving line 320 can include a plurality of holes 325 and 326 in an area intersecting a sensing line. Although two holes 325 and 326 in addition to the first groove 323 and the second groove 324 are shown in FIG. 6, this is for exemplary purposes only and embodiments are not limited thereto. In various embodiments, three holes, four holes, five holes, six holes, seven holes, eight holes, or more can be formed. For example, at least two holes or at least three holes can be formed.

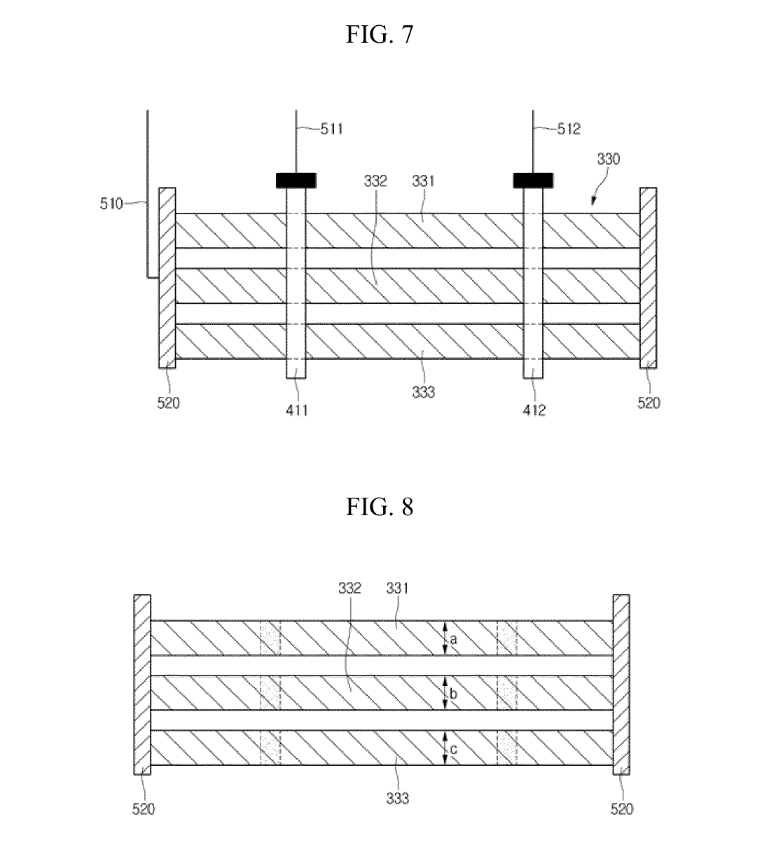

Referring to FIG. 7, in another embodiment, a driving line 330 can include a plurality of unit lines connected to the contact unit 520. That is, one driving line 330 can include a plurality of divided sub lines 331, 332, and 333. This is also to reduce an area intersecting a sensing line. Referring to FIG. 8, the driving line 330 can include first to third sub lines 331, 332, and 333. These sub lines can configure one single driving line, so that they are connected to the same contact unit 520.

Although three divided sub lines 331, 332, 333 are shown in FIGS. 7 and 8, this is for exemplary purposes only and embodiments are not limited thereto. In various embodiments, two, three, four, five, six, seven, eight, or more divided sub lines can be formed. For example, at least two divided sub lines, at least three divided sub lines, or at least four divided sub lines can be formed.

The widths a, b, and c of the first to third sub lines 331, 332, 333 can be the same or can vary according to various embodiments of the subject invention. That is, in an embodiment, the widths a, b, and c are all the same or approximately the same. In another embodiment, widths a and b are the same or approximately the same while width c is smaller than widths a and b. In another embodiment, widths a and b are the same or approximately the same while width c is larger than widths a and b. In another embodiment, widths a and c are the same or approximately the same while width b is smaller than widths a and c. In another embodiment, widths a and c are the same or approximately the same while width b is larger than widths a and c. In another embodiment, widths b and c are the same or approximately the same while width a is smaller than widths b and c. In another embodiment, widths b and c are the same or approximately the same while width a is larger than widths b and c. In another embodiment, widths a, b, and c are all different. For example, the widths in descending order from largest to smallest can be: a>b>c; a>c>b; b>a>c; b>c>a; c>a>b; or c>b>a. This same principle applies if a number of divided sub lines other than three is present.

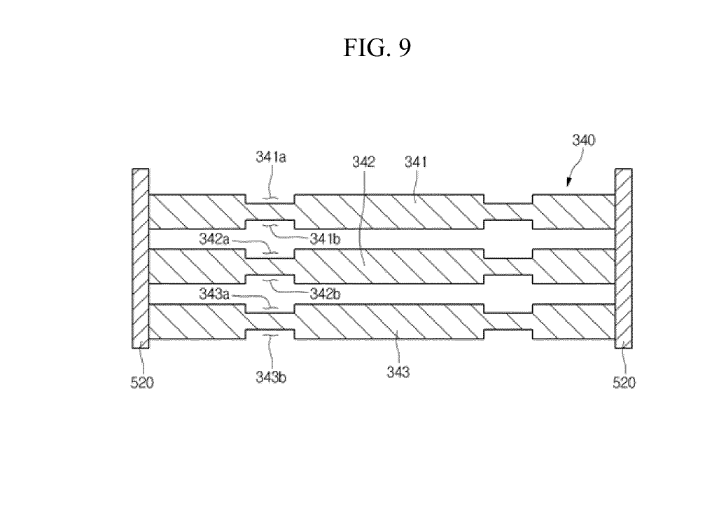

Referring to FIG. 9, one driving line 340 can includes first, second, and third divided sub lines 341, 342, and 343. Also, each of the divided sub lines 341, 342, and 343 can include at least one groove in an area intersecting a sensing line.

For example, a first groove 341a and a second groove 341b can be formed in an area intersecting a sensing line in the first sub line 341, so that an area where the first sub line 341 and the sensing line intersect each other can be reduced. A first groove 342a and a second groove 342b can be formed in an area intersecting a sensing line in the second sub line 342, so that an area where the second sub line 342 and the sensing line intersect each other can be reduced. a first groove 343a and a second groove 343b can be formed in an area intersecting a sensing line in the third sub line 343, so that an area where the third sub line 343 and the sensing line intersect each other can be reduced. Moreover, all potential variations discussed above with respect to FIGS. 4-8 (e.g., number of grooves, number of divided sub lines) apply to the embodiment depicted in FIG. 9.

According to embodiments of the subject invention, an intersection area where a driving line and a sensing line intersect in the X axis and the Y axis can be advantageously reduced. Due to the reduction of the intersection area, parasitic capacitance can be reduced and touch recognition sensitivity can be improved.

Also, in embodiments of the present invention, the form of a driving line can reduce parasitic capacitance without adding any additional processes, so that touch sensitivity can be improved in a cost-effective manner.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

What is claimed is:

1. A touch screen panel, comprising:
a plurality of driving lines arranged in a first direction; and
a plurality of sensing lines arranged in a direction perpendicular to and intersecting the first direction;
wherein each driving line comprises, in an area intersecting a sensing line: at least one hole, at least one groove, or both.

2. The touch screen panel according to claim 1, wherein each driving line comprises at least one groove in an area intersecting a sensing line, and
wherein the at least one groove has a shape recessed from a lateral side of the driving line toward the inner portion of the driving line.

3. The touch screen panel according to claim 2, wherein each driving line comprises at least one hole in an area intersecting a sensing line,
wherein each driving line comprises two grooves in an area intersecting a sensing line, one groove on each lateral side of the driving line, and
wherein the at least one hole is provided between the two grooves along a direction of the intersected sensing line.

4. The touch screen panel according to claim 3, wherein each driving line comprises at least two holes in an area intersecting a sensing line, and
wherein each hole is provided between the two grooves along a direction of the intersected sensing line.

5. The touch screen panel according to claim 1, wherein each driving line comprises a plurality of intersection areas where sensing lines are intersected, one for each sensing line intersected.

6. The touch screen panel according to claim 5, wherein each intersection area comprises two grooves, one groove recessed from each lateral side of the driving line toward the inner portion of the driving line.

7. The touch screen panel according to claim 6, wherein each intersection area comprises at least one hole, and
wherein the at least one hole is provided between the two grooves along a direction of the intersected sensing line.

8. The touch screen panel according to claim 6, wherein each intersection area comprises at least two holes, and
wherein each hole is provided between the two grooves along a direction of the intersected sensing line.

9. The touch screen panel according to claim 5, wherein each intersection area comprises at least one hole.

10. A touch screen panel, comprising:
a plurality of driving lines arranged in a first direction;
a plurality of sensing lines arranged in a direction perpendicular to and intersecting the first direction;
a plurality of trace lines electrically connected to the driving lines, respectively, such that each driving line is electrically connected to one trace line; and
a plurality of contact units in direct physical contact with the driving lines, respectively, such that each driving line is in direct physical contact with one contact unit,
wherein each of the driving lines comprises a plurality of divided sub lines all connected to the same contact unit.

11. The touch screen panel according to claim 10, wherein each divided sub line comprises, in an area intersecting a sensing line: at least one hole, at least one groove, or both.

12. The touch screen panel according to claim 11, wherein each divided sub line comprises at least one groove in an area intersecting a sensing line, and
wherein the at least one groove has a shape recessed from a lateral side of the divided sub line toward the inner portion of the divided sub line.

13. The touch screen panel according to claim 12, wherein each divided sub line comprises at least one hole in an area intersecting a sensing line,
wherein each divided sub line comprises two grooves in an area intersecting a sensing line, one groove on each lateral side of the divided sub line, and
wherein the at least one hole is provided between the two grooves along a direction of the intersected sensing line.

14. The touch screen panel according to claim 13, wherein each divided sub line comprises at least two holes in an area intersecting a sensing line, and
wherein each hole is provided between the two grooves along a direction of the intersected sensing line.

15. The touch screen panel according to claim 1, wherein each divided sub line comprises a plurality of intersection areas where sensing lines are intersected, one for each sensing line intersected.

16. The touch screen panel according to claim 15, wherein each intersection area comprises two grooves, one groove recessed from each lateral side of the divided sub line toward the inner portion of the divided sub line.

17. The touch screen panel according to claim 16, wherein each intersection area comprises at least one hole, and
wherein the at least one hole is provided between the two grooves along a direction of the intersected sensing line.

18. The touch screen panel according to claim 16, wherein each intersection area comprises at least two holes, and
wherein each hole is provided between the two grooves along a direction of the intersected sensing line.

19. The touch screen panel according to claim 15, wherein each intersection area comprises at least one hole.

20. A method of fabricating a touch screen panel, the method comprising:
forming a plurality of driving lines arranged in a first direction;
forming a plurality of sensing lines arranged in a direction perpendicular to and intersecting the first direction; and
forming on each driving line, in an area intersecting a sensing line: at least one hole, at least one groove, or both.
